(19) United States
(12) Patent Application Publication
(10) Pub. No.: US 2026/0275019 A1
(43) Pub. Date: Sep. 17, 2026

(54) RESIST POLYMER, PHOTOSENSITIVE RESIN COMPOSITION, INTERLAYER INSULATING FILM, AND POLYMER PRODUCTION METHOD

(71) Applicant: NIPPON SHOKUBAI CO., LTD., Osaka-shi, Osaka (JP)

(72) Inventors: Takuma TERADA, Osaka (JP); Hiroaki TAKAHASHI, Osaka (JP); Nobuaki OTSUKI, Osaka (JP)

(21) Appl. No.: 19/167,183

(22) PCT Filed: Mar. 21, 2024
(86) PCT No.: PCT/JP2024/010945

§ 371 Date: Sep. 19, 2025

(30) Foreign Application Priority Data
Mar. 31, 2023 (JP) 2023-058194
Dec. 19, 2023 (JP) 2023-213924

(51) Int. Cl. C08F 290/12; C08F 2/06; C08F 2/38; C08F 2/50; C08F 8/00; C08F 222/40; C08K 5/14; C08L 55/00; G03F 7/11

(52) U.S. Cl. CPC C08F 290/126; C08F 2/06; C08F 2/38; C08F 8/00; C08F 222/402; C08K 5/14; C08L 55/005; G03F 7/11; C08F 2/50; C08L 2205/05

(57) ABSTRACT

The present disclosure provides a resist polymer and a photosensitive resin composition that are excellent in photocurability, alkali solubility, and heat resistance, as well as in thermomechanical properties and moisture resistance. The present disclosure relates to a resist polymer containing: a structural unit (A) derived from a maleimide-based monomer; a structural unit (B) derived from an aromatic monomer; and a structural unit (C) derived from an acid group-containing monomer, an amount of a structural unit (D) derived from a primary hydroxy group-containing monomer being less than 5% by mass based on 100% by mass of all structural units of the polymer, the polymer having an imide equivalent weight of 670 g/eq or less.

### TECHNICAL FIELD

The present disclosure relates to resist polymers, photosensitive resin compositions, interlayer insulating films, and methods for producing polymers. Specifically, the present disclosure relates to a resist polymer, a photosensitive resin composition, and an interlayer insulating film that are excellent in heat resistance, alkali solubility, and photocurability, as well as in thermomechanical properties and moisture resistance. The present invention also relates to a method for producing a polymer.

### BACKGROUND ART

Alkali-soluble resins and photosensitive resin compositions have been extensively studied for various applications, such as color filters used in devices such as liquid crystal display devices and solid-state imaging devices, inks, printing plates, printed wiring boards, semiconductor devices, photoresists, organic insulating films, and organic protective films, and other optical components and electrical/electronic devices. Resins and resin compositions excellent in the properties required for these applications have been developed.

In recent years, miniaturization, thinning, and energy-saving of optical components and electrical/electronic devices have been progressing, and accordingly, higher-quality performance of various components used in these devices is increasingly demanded. To meet such demands, research has been conducted on alkali-soluble resins with further improved properties.

Resins used for resist applications require properties such as photocurability, alkali solubility, and heat resistance. Alkali-soluble resins excellent in such properties have been developed for resist use.

For example, Patent Literature 1 describes a maleimide-based copolymer, as a polymer excellent in heat resistance, flow thermal stability, and alkali solubility, obtained by polymerizing a monomer component including an N-substituted maleimide-based monomer, an aromatic vinyl monomer, and an unsaturated monocarboxylic acid monomer.

Furthermore, for example, Patent Literature 2 describes a polymer obtained by polymerizing an N-substituted maleimide-based monomer, an ether dimer, vinyl toluene, and an acid group-containing monomer as essential components, as a polymer that has excellent heat resistance, can reduce gas generation upon heating, and has a high dissolution rate in an organic solvent or an alkali.

Furthermore, for example, Patent Literature 3 describes a curable resin composition including a radical polymerizable polymer that contains, as essential units, a structural unit derived from a maleimide-based monomer, a structural unit derived from an unsaturated carboxylic acid monomer having no ester bond, and a structural unit derived from a hydroxy group-containing monomer and that has a structure obtained by reacting carboxy groups of a polymer, which is a base polymer, with a monomer having a functional group capable of reacting with the carboxy groups.

### CITATION LIST

### Patent Literature

Patent Literature 1: JP 2002-30119 A
Patent Literature 2: JP 2009-40999 A
Patent Literature 3: JP 2019-174761 A

### SUMMARY OF INVENTION

### Technical Problem

However, conventional alkali-soluble resins have not yet been fully studied in terms of moisture resistance and thermomechanical properties such as low coefficient of linear expansion. When a resin composition containing an alkali-soluble resin is used as a material of an interlayer insulating film for a semiconductor, the resin composition requires moisture resistance and low coefficient of linear expansion to ensure good adhesion to a substrate.

The present disclosure has been made in view of the above circumstances, and aims to provide a resist polymer and a photosensitive resin composition that are excellent in photocurability, alkali solubility, and heat resistance, as well as in thermomechanical properties and moisture resistance.

### Solution to Problem

The present inventors have conducted various studies on alkali-soluble resins and found that a polymer containing a large amount of structural units derived from maleimide-based monomers, namely, a polymer with a low imide equivalent weight, can have an improved glass transition temperature and a low coefficient of linear expansion. They also found that when the polymer contains an aromatic ring and/or a reduced amount of primary hydroxy groups, the polymer can have low polarity and thus can have improved moisture resistance. The present inventors then found that a polymer in which the amount of a structural unit derived from a primary hydroxy group-containing monomer falls within a specific range, and which contains three specific types of structural units and has an imide equivalent weight within a specific range is excellent in photocurability, alkali solubility, heat resistance, and moisture resistance, and the polymer can provide a cured product having a low coefficient of linear expansion and excellent in thermomechanical properties. Thus, the present disclosure has been completed.

Specifically, the present disclosure provides the following aspects.
(1) A resist polymer containing:
a structural unit (A) derived from a maleimide-based monomer;
a structural unit (B) derived from an aromatic monomer; and
a structural unit (C) derived from an acid group-containing monomer,
an amount of a structural unit (D) derived from a primary hydroxy group-containing monomer being less than 5% by mass based on 100% by mass of all structural units of the polymer,
the polymer having an imide equivalent weight of 670 g/eq or less.
(2) The resist polymer according to (1) above,
wherein the polymer has an ester bond equivalent weight of 500 g/eq or more.
(3) The resist polymer according to (1) or (2) above, further containing a structural unit (E) containing a polymerizable double bond in a side chain.
(4) The resist polymer according to (3) above,
wherein the structural unit (E) includes a structural unit represented by the following formula (1):

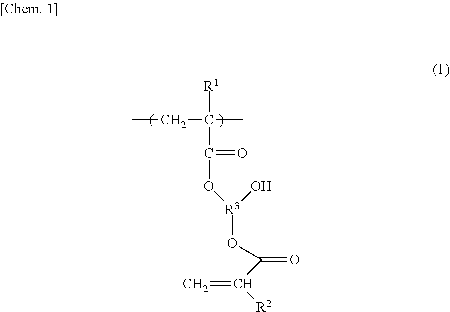

wherein R¹ and R² are the same as or different from each other and each represent a hydrogen atom or a C1-C6 hydrocarbon group; and R³ represents a C1-C10 trivalent hydrocarbon group.
(5) The resist polymer according to any one of (1) to (4) above,
wherein the structural unit (B) derived from an aromatic monomer includes a structural unit represented by the following formula (2):

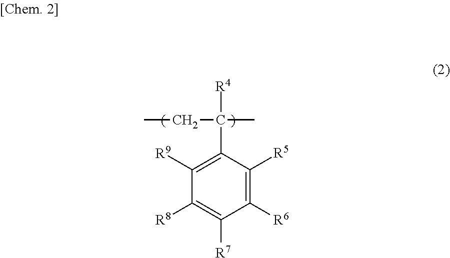

wherein R⁴ to R⁹ are the same as or different from each other and each represent a hydrogen atom or a C1-C6 hydrocarbon group.
(6) The resist polymer according to any one of (1) to (5) above,
wherein the polymer has a weight average molecular weight of 20,000 or less.
(7) A photosensitive resin composition containing:
the resist polymer according to any one of (1) to (6) above; and
an organic solvent.
(8) The photosensitive resin composition according to (7) above, further containing a thermal crosslinking agent.
(9) An interlayer insulating film including a cured product of the photosensitive resin composition according to (7) or (8) above.
(10) A method for producing a polymer, including
polymerizing a monomer component in the presence of a solvent,
the monomer component including a maleimide-based monomer (a) in an amount of 35 to 60% by mass, an aromatic monomer (b) in an amount of 10 to 60% by mass, and an acid group-containing monomer (c) in an amount of 5 to 30% by mass, in 100% by mass of the monomer component,
an amount of a primary hydroxy group-containing monomer (d) in 100% by mass of the monomer component being less than 5% by mass,
the solvent including an ester solvent.

### Advantageous Effects of Invention

The resist polymer of the present disclosure and a photosensitive resin composition containing the resist polymer are excellent in photocurability and alkali solubility, and can provide a cured product excellent in heat resistance, moisture resistance, and thermomechanical properties. The resist polymer and photosensitive resin composition of the present disclosure are suitably used for various applications such as interlayer insulating films.

### DESCRIPTION OF EMBODIMENTS

The present disclosure is described in detail below.

Any combination of two or more of the following preferred embodiments of the present disclosure is also a preferred embodiment of the present disclosure.

Herein, “(meth)acrylic acid” refers to “acrylic acid and/or methacrylic acid”, and “(meth)acrylate” refers to “acrylate and/or methacrylate”.

### 1. Resist Polymer

The present disclosure relates to a resist polymer containing: a structural unit (A) derived from a maleimide-based monomer; a structural unit (B) derived from an aromatic monomer; and a structural unit (C) derived from an acid group-containing monomer, an amount of a structural unit (D) derived from a primary hydroxy group-containing monomer being less than 5% by mass based on 100% by mass of all structural units of the polymer, the polymer having an imide equivalent weight of 670 g/eq or less.

The resist polymer of the present disclosure is excellent in photocurability and alkali solubility, and can provide a cured product excellent in heat resistance, moisture resistance, and thermomechanical properties. It is believed that the resist polymer of the present disclosure can exhibit such effects for the following reasons. Containing a structural unit derived from a maleimide-based monomer and having an imide equivalent weight equal to or lower than a predetermined level, namely, containing a structural unit derived from a maleimide-based monomer in an amount equal to or larger than a predetermined amount, allows the polymer to have improved heat resistance and low coefficient of linear expansion. Furthermore, containing a structural unit derived from an aromatic monomer and containing a primary hydroxy group in an amount equal to or smaller than a predetermined amount allows the polymer to have low hydrophilicity and improved moisture resistance. Furthermore, containing a structural unit derived from an acid group-containing monomer allows the polymer to exhibit alkali solubility.

The structural units constituting the resist polymer of the present disclosure are each described. Herein, the term “structural unit(s)” refers to a repeating (structural) unit derived from a monomer constituting a polymer.

### Structural Unit (A)

The resist polymer of the present disclosure contains a structural unit (A) derived from a maleimide-based monomer. The presence of a structural unit (A) can improve heat resistance and thermomechanical properties.

An example of the structural unit (A) is a structural unit represented by the following formula (3):

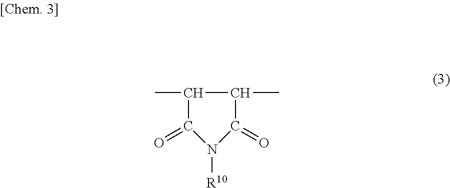

wherein R¹⁰ represents a hydrogen atom or a C1-C20 hydrocarbon group.

The hydrocarbon group for R¹⁰ may be linear or cyclic, and may be saturated or unsaturated. In particular, to provide a cured product with good properties, the hydrocarbon group is preferably a cyclic unsaturated hydrocarbon group, more preferably an aromatic hydrocarbon group.

Examples of a linear saturated hydrocarbon group include alkyl groups such as a methyl group, an ethyl group, an n-propyl group, an isopropyl group, an n-butyl group, a tert-butyl group, a sec-butyl group, a pentyl group, an isopentyl group, a neopentyl group, a hexyl group, a 2-methylpentyl group, a heptyl group, a 2-methylhexyl group, a 2,2-dimethylpentyl group, a 3-ethylpentyl group, an octyl group, a methylheptyl group, a dimethylhexyl group, a nonyl group, and a decyl group.

Examples of a linear unsaturated hydrocarbon group include a vinyl group, an n-propenyl group, an isopropenyl group, a 1-butenyl group, a 1-pentenyl group, a 2-methyl-1-butenyl group, and a 1-hexenyl group.

Examples of a cyclic saturated hydrocarbon group include cycloalkyl groups such as a cyclopropyl group, a cyclobutyl group, a cyclopentyl group, a cyclohexyl group, a norbornyl group, and an adamantyl group.

Examples of a cyclic unsaturated hydrocarbon group include cycloalkenyl groups such as a cyclopropenyl group, a cyclobutenyl group, a cyclopentenyl group, and a cyclohexenyl group; and aromatic hydrocarbon groups such as an aryl group (e.g., a phenyl group, a tolyl group, a xylyl group, or a naphthyl group) and an aralkyl group (e.g., a benzyl group, a phenethyl group, or a phenylpropyl group).

To impart good heat resistance and moisture resistance, the hydrocarbon group preferably has 1 to 15 carbon atoms, more preferably 1 to 10 carbon atoms, still more preferably 6 or 7 carbon atoms.

In the hydrocarbon group, at least one of the hydrogen atoms constituting the hydrocarbon group may be replaced by a halogen atom, a hydroxy group, an alkyl group, or the like.

The polymer containing a structural unit (A) can be obtained by polymerizing a monomer component including a maleimide-based monomer (a). Examples of the maleimide-based monomer (a) include maleimide and N-substituted maleimide. To impart good heat resistance and moisture resistance, N-substituted maleimide is preferred.

Examples of the N-substituted maleimide include N-cyclohexylmaleimide, N-phenylmaleimide, N-methylmaleimide, N-ethylmaleimide, N-isopropylmaleimide, N-t-butylmaleimide, N-dodecylmaleimide, N-benzylmaleimide, and N-naphthylmaleimide. One or more of these can be used. Of these, to impart good heat resistance and moisture resistance, N-phenylmaleimide and N-benzylmaleimide are preferred, with N-benzylmaleimide being more preferred.

Examples of the N-phenylmaleimide include phenylmaleimide; alkyl-substituted phenylmaleimides such as p-methylphenylmaleimide and p-butylphenylmaleimide; phenolic hydroxy group-substituted phenylmaleimides such as p-hydroxyphenylmaleimide; and halogen-substituted phenylmaleimides such as o-chlorophenylmaleimide, o-dichlorophenylmaleimide, and p-dichlorophenylmaleimide.

Examples of the N-benzylmaleimide include benzylmaleimide; alkyl-substituted benzylmaleimides such as p-methylbenzylmaleimide and p-butylbenzylmaleimide; phenolic hydroxy group-substituted benzylmaleimides such as p-hydroxybenzylmaleimide; and halogen-substituted benzylmaleimides such as o-chlorobenzylmaleimide, o-dichlorobenzylmaleimide, and p-dichlorobenzylmaleimide.

The resist polymer may contain only one type of the structural unit (A), or two or more types of the structural unit (A).

To impart sufficient heat resistance and moisture resistance, the amount of the structural unit (A) is preferably 35 to 60% by mass based on 100% by mass of all structural units of the resist polymer. To impart a good balance between heat resistance and alkaline developability, the amount of the structural unit (A) is more preferably 40 to 55% by mass, still more preferably 45 to 50% by mass, based on 100% by mass of all structural units of the polymer.

### Structural Unit (B)

The resist polymer of the present disclosure contains a structural unit (B) derived from an aromatic monomer. The presence of a structural unit (B) can improve moisture resistance and heat resistance.

The polymer containing a structural unit (B) can be obtained by polymerizing a monomer component including an aromatic monomer (b). An example of the aromatic monomer (b) is a compound having an aromatic group and a polymerizable functional group.

The polymerizable functional group may be a group having a polymerizable double bond, such as a (meth)acryloyl group, a vinyl group, an allyl group, or a methallyl group. Of these, a (meth)acryloyl group is preferred to impart high polymerizability, versatility, and supply stability.

Examples of the aromatic group include aryl groups such as a phenyl group, an o-tolyl group, an m-tolyl group, a p-tolyl group, a 2,3-xylyl group, a 2,4-xylyl group, a 2,5-xylyl group, a 2,6-xylyl group, a 3,4-xylyl group, a 3,5-xylyl group, and a 1-naphthyl group, and aralkyl groups such as a benzyl group.

Specific examples of the aromatic monomer (b) include styrene, vinyltoluene, α-methylstyrene, and methoxystyrene. Of these, styrene and vinyltoluene are preferred to impart good heat resistance and moisture resistance, and vinyltoluene is more preferred to impart excellent electrical insulating properties and developability.

A preferred example of the structural unit (B) is a structural unit represented by the formula (2) below. The structural unit represented by the formula (2) has a structure in which the aromatic ring is directly bonded to the main chain, which reduces the likelihood of thermal decomposition and results in better heat resistance.

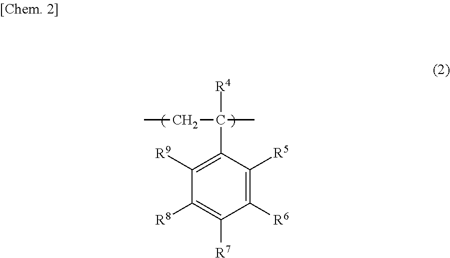

In the formula, R⁴ to R⁹ are the same as or different from each other and each represent a hydrogen atom or a C1-C6 hydrocarbon group.

In the formula (2), R⁴ to R⁹ are the same as or different from each other and each represent a hydrogen atom or a C1-C6 hydrocarbon group. Examples of the hydrocarbon group for R⁴ to R⁹ include C1-C6 hydrocarbon groups among the hydrocarbon groups for R¹⁰ listed above. Of these, to impart good heat resistance and moisture resistance, saturated hydrocarbon groups are preferred, with alkyl groups being more preferred.

R⁴ is preferably a hydrogen atom or a methyl group.

R⁵ to R⁹ are the same as or different from each other and are preferably C1-C10 saturated hydrocarbon groups, more preferably C1-C5 alkyl groups, still more preferably C1-C3 alkyl groups.

The resist polymer may contain only one type of the structural unit (B), or two or more types of the structural unit (B).

To impart sufficient heat resistance and moisture resistance, the amount of the structural unit (B) is preferably 10 to 60% by mass based on 100% by mass of all structural units of the resist polymer. To impart a good balance between heat resistance and alkaline developability, the amount of the structural unit (B) is more preferably 20 to 50% by mass, still more preferably 30 to 40% by mass, based on 100% by mass of all structural units of the polymer.

### Structural Unit (C)

The resist polymer contains a structural unit (C) derived from an acid group-containing monomer. The resist polymer containing a structural unit (C) is alkali-soluble.

The polymer containing a structural unit (C) can be obtained by polymerizing a monomer component including an acid group-containing monomer (c). An example of the acid group-containing monomer is a compound having an acid group and a polymerizable functional group.

Examples of the polymerizable functional group include groups listed above as the group having a polymerizable double bond. Of these, a (meth)acryloyl group is preferred.

Examples of the acid group include functional groups that undergo a neutralizing reaction with alkaline water, such as a carboxy group, a phenolic hydroxy group, a carboxylic anhydride group, a phosphoric acid group, and a sulfonic acid group. Of these, a carboxy group is preferred.

Examples of the acid group-containing monomer include unsaturated monocarboxylic acids such as (meth)acrylic acid, crotonic acid, cinnamic acid, and vinylbenzoic acid; unsaturated polycarboxylic acids such as maleic acid, fumaric acid, itaconic acid, citraconic acid, and mesaconic acid; long-chain unsaturated monocarboxylic acids having an extended chain between the unsaturated group and the carboxy group, such as β-carboxyethyl (meth)acrylate, mono(2-acryloyloxyethyl) succinate, and mono(2-methacryloyloxyethyl) succinate; unsaturated acid anhydrides such as maleic anhydride and itaconic anhydride; and phosphate group-containing unsaturated compounds such as Light Ester P-1M (Kyoeisha Chemical Co., Ltd.). Of these, from the viewpoints of versatility, availability, and the like, carboxylic acid monomers (unsaturated monocarboxylic acids, unsaturated polycarboxylic acids, long-chain unsaturated monocarboxylic acids, unsaturated acid anhydrides) are preferred. From the viewpoints of reactivity, alkali solubility, and the like, the acid group-containing monomer is more preferably an unsaturated monocarboxylic acid, still more preferably (meth)acrylic acid.

A preferred example of the structural unit (C) is a structural unit represented by the following formula (4):

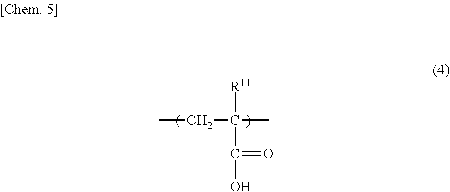

wherein R¹¹ represents a hydrogen atom or a C1-C6 hydrocarbon group.

Examples of the hydrocarbon group for R¹¹ in the formula (4) include C1-C6 hydrocarbon groups among the hydrocarbon groups for R¹⁰ listed above. Of these, to impart good heat resistance and moisture resistance, saturated hydrocarbon groups are preferred, with alkyl groups being more preferred.

R¹¹ is preferably a hydrogen atom or a methyl group.

The resist polymer may contain only one type of the structural unit (C), or two or more types of the structural unit (C).

To impart a good balance of properties such as heat resistance and moisture resistance while achieving good alkaline developability, the amount of the structural unit (C) is preferably 5 to 30% by mass, more preferably 10 to 25% by mass, still more preferably 15 to 20% by mass, based on 100% by mass of all structural units of the resist polymer.

### Structural Unit (D)

The resist polymer of the present disclosure may further contain a structural unit (D) derived from a primary hydroxy group-containing monomer, but the amount of the structural unit (D) is less than 5% by mass based on 100% by mass of all structural units of the resist polymer. If the amount of the structural unit (D) in the resist polymer of the present disclosure is 5% by mass or more based on 100% by mass of all structural units of the polymer, the hydrophilicity of the polymer increases, which reduces the moisture resistance of the cured product and thus may impair its physical properties. To impart better moisture resistance, the amount of the structural unit (D) is preferably 4.5% by mass or less, more preferably 4% by mass or less, still more preferably 3.5% by mass or less, particularly preferably 2.5% by mass or less, based on 100% by mass of all structural units of the polymer.

The polymer containing a structural unit (D) can be obtained by polymerizing a monomer component including a primary hydroxy group-containing monomer (d). An example of the primary hydroxy group-containing monomer is a compound having a primary hydroxy group and a polymerizable functional group.

Examples of the polymerizable functional group include groups listed above as the group having a polymerizable double bond. Of these, a (meth)acryloyl group is preferred.

Examples of the primary hydroxy group-containing monomer (d) include hydroxyalkyl (meth)acrylates such as 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, and 2,3-hydroxypropyl (meth)acrylate; and hydroxyalkyl (meth)acrylamides such as 2-hydroxymethyl (meth)acrylamide, 2-hydroxyethyl (meth)acrylamide, 2-hydroxypropyl (meth)acrylamide, 3-hydroxypropyl (meth)acrylamide, 4-hydroxybutyl (meth)acrylamide, hydroxypivalyl (meth)acrylamide, 5-hydroxypentyl (meth)acrylamide, and 6-hydroxyhexyl (meth)acrylamide.

### Structural Unit (E)

The resist polymer of the present disclosure may further contain a structural unit (E) having a polymerizable double bond in a side chain. The presence of a structural unit (E) can improve photocurability.

Examples of the polymerizable double bond include those listed above. Of these, a (meth)acryloyl group is preferred.

As for the structural unit (E), for example, a polymerizable double bond may be introduced into a side chain by a method including polymerizing a monomer component including an acid group-containing monomer to obtain a base polymer containing a structural unit (C) and then reacting an acid group of the obtained base polymer with a compound having an epoxy group and a polymerizable double bond, or a polymerizable double bond may be introduced into a side chain by a method including polymerizing a monomer component including an epoxy group-containing monomer to obtain a base polymer, and then reacting an epoxy group of the obtained base polymer with an acid group-containing monomer.

An example of the compound having an epoxy group and a polymerizable double bond is an epoxy group-containing monomer. Examples of the epoxy group-containing monomer include epoxy group-containing monomers which are described below for the structural unit (F).

A preferred example of the structural unit (E) is a structural unit represented by the following formula (1):

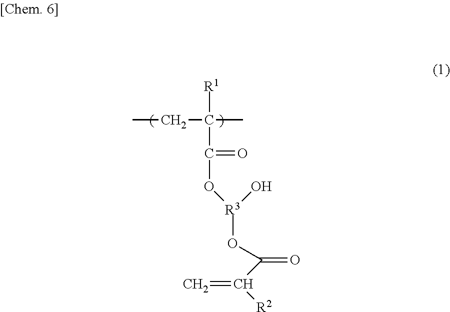

wherein R¹ and R² are the same as or different from each other and each represent a hydrogen atom or a C1-C6 hydrocarbon group; and R³ represents a C1-C10 trivalent hydrocarbon group.

Examples of the C1-C6 hydrocarbon group for R¹ and R² in the formula (1) include C1-C6 hydrocarbon groups among the hydrocarbon groups for R¹⁰ listed above. Of these, saturated hydrocarbon groups are preferred, with alkyl groups being more preferred.

R¹ and R² are each preferably a hydrogen atom or a methyl group.

The trivalent hydrocarbon group for R³ is preferably a trivalent saturated hydrocarbon group. The trivalent hydrocarbon group preferably has 1 to 20 carbon atoms, more preferably 2 to 10 carbon atoms, still more preferably 3 to 7 carbon atoms.

Examples of the trivalent hydrocarbon group for R³ include the following groups.

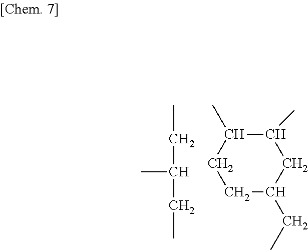

The resist polymer may contain only one type of the structural unit (E), or two or more types of the structural unit (E).

### Structural Unit (F)

The resist polymer may further contain a structural unit (F) different from the structural units (A) to (E).

Examples of the different structural unit (F) include structural units derived from the following monomers:
(meth)acrylate monomers such as methyl (meth)acrylate, ethyl (meth)acrylate, n-propyl (meth)acrylate, i-propyl (meth)acrylate, n-butyl (meth)acrylate, s-butyl (meth)acrylate, n-amyl (meth)acrylate, s-amyl (meth)acrylate, n-hexyl (meth)acrylate, 2-ethylhexyl (meth)acrylate, isodecyl (meth)acrylate, tridecyl (meth)acrylate, octyl (meth)acrylate, isooctyl (meth)acrylate, lauryl (meth)acrylate, stearyl (meth)acrylate, benzyl (meth)acrylate, phenyl (meth)acrylate, isobornyl (meth)acrylate, adamantyl (meth)acrylate, tricyclodecanyl (meth)acrylate, cyclohexyl (meth)acrylate, dicyclopentanyl (meth)acrylate, 2-methoxyethyl (meth)acrylate, 2-ethoxyethyl (meth)acrylate, tetrahydrofurfuryl (meth)acrylate, N,N-dimethylaminoethyl (meth)acrylate, 1,4-dioxaspiro[4,5]dec-2-yl methacrylate, (meth)acryloylmorpholine, 4-(meth)acryloyloxymethyl-2-methyl-2-ethyl-1,3-dioxolane, 4-(meth)acryloyloxymethyl-2-methyl-2-isobutyl-1,3-dioxolane, 4-(meth)acryloyloxymethyl-2-methyl-2-cyclohexyl-1,3-dioxolane, and 4-(meth)acryloyloxymethyl-2,2-dimethyl-1,3-dioxolane; epoxy group-containing monomers such as glycidyl (meth)acrylate, P-methylglycidyl (meth)acrylate, β-ethylglycidyl (meth)acrylate, vinylbenzyl glycidyl ether, allyl glycidyl ether, (3,4-epoxycyclohexyl)methyl (meth)acrylate, and vinylcyclohexene oxide; (meth)acrylamides such as N,N-dimethyl(meth)acrylamide and N-methylol(meth)acrylamide;
macromonomers having a (meth)acryloyl group at one end of a polymer molecular chain, such as polystyrene, polymethyl (meth)acrylate, polyethylene oxide, polypropylene oxide, polysiloxane, polycaprolactone, and polycaprolactam; conjugated dienes such as 1,3-butadiene, isoprene, and chloroprene; vinyl esters such as vinyl acetate, vinyl propionate, vinyl butyrate, and vinyl benzoate; vinyl ethers such as methyl vinyl ether, ethyl vinyl ether, propyl vinyl ether, butyl vinyl ether, 2-ethylhexyl vinyl ether, n-nonyl vinyl ether, lauryl vinyl ether, cyclohexyl vinyl ether, methoxyethyl vinyl ether, ethoxyethyl vinyl ether, methoxyethoxyethyl vinyl ether, methoxypolyethylene glycol vinyl ether, 2-hydroxyethyl vinyl ether, and 4-hydroxybutyl vinyl ether;
N-vinyl compounds such as N-vinylpyrrolidone, N-vinylcaprolactam, N-vinylimidazole, N-vinylmorpholine, and N-vinylacetamide; and
unsaturated isocyanates such as isocyanatoethyl (meth)acrylate and allyl isocyanate.

The resist polymer may contain only one type of the structural unit (F), or two or more types of the structural unit (F).

To impart good photocurability, the amount of the structural unit (F) is preferably 3 to 30% by mass, more preferably 5 to 25% by mass, still more preferably 7 to 20% by mass, based on 100% by mass of all structural units of the resist polymer.

The resist polymer has an imide equivalent weight of 670 g/eq or less. When the imide equivalent weight is within the above range, the heat resistance and thermomechanical properties can be further improved. To impart a good balance of properties such as heat resistance and alkaline developability, the imide equivalent weight is preferably 300 to 650 g/eq, more preferably 350 to 600 g/eq, still more preferably 400 to 550 g/eq.

The imide equivalent weight can be determined by dividing the mass (g) of solids in the polymer solution by the amount (mol) of imide groups in the polymer.

The resist polymer preferably has an ester bond equivalent weight of 500 g/eq or more. When the ester bond equivalent weight is within the above range, the heat resistance can be further improved. To impart a good balance of properties such as heat resistance, photocurability, and alkaline developability, the ester bond equivalent weight is more preferably 600 to 10,000 g/eq, still more preferably 650 to 5,000 g/eq, particularly preferably 700 to 3,000 g/eq.

The ester bond equivalent weight can be determined by dividing the mass (g) of solids in the polymer solution by the amount (mol) of ester bonds in the polymer.

To impart a good balance of properties such as heat resistance and alkaline developability, the resist polymer preferably has a weight average molecular weight of 20,000 or less, more preferably 2,000 to 18,000, still more preferably 3,000 to 15,000, further more preferably 4,000 to 10,000.

The weight average molecular weight can be measured by the method described in the EXAMPLES using gel permeation chromatography (GPC).

The resist polymer preferably has an acid value of 80 to 200 mgKOH/g. When the acid value is within the above range, the resist polymer easily exhibits good alkaline developability. To prevent the exposed portions from being easily eroded by an alkaline developer, the acid value is more preferably 90 to 180 mgKOH/g, still more preferably 100 to 150 mgKOH/g.

The acid value can be measured by neutralization titration with a KOH solution, and can be specifically measured by the method described in the EXAMPLES.

When having a polymerizable double bond in a side chain, the resist polymer preferably has a double bond equivalent weight of 800 to 5,000 g/eq, more preferably 900 to 4,000 g/eq, still more preferably 1,000 to 3,000 g/eq.

The double bond equivalent weight can be determined by dividing the mass (g) of the polymer solids by the amount (mol) of double bonds in the polymer. The double bond herein refers to a radically polymerizable double bond. In other words, the double bond refers to polymerizable double bonds in groups typified by a (meth)acryloyl group. For example, a double bond generated by adding tetrahydrophthalic anhydride to a hydroxy group has no reactivity and thus shall not be included in the calculation of the double bond equivalent weight. The amount of double bonds in the polymer can be determined by ¹H-NMR measurement or iodometric titration.

### <Method for Producing Resist Polymer>

The resist polymer may be produced by any method capable of polymerizing a monomer component to obtain a desired polymer, and known polymerization methods can be used.

The polymerization of the monomer component may be performed by any method, and a commonly used technique such as bulk polymerization, solution polymerization, or emulsion polymerization may be used. Of these, solution polymerization is preferred because it is industrially advantageous and allows easy adjustment of the structure of the polymer, such as the molecular weight. The polymerization of the monomer component may be performed by a polymerization method based on the mechanism of radical polymerization, anionic polymerization, cationic polymerization, or coordination polymerization. From the viewpoint of industrial advantages, a polymerization method based on the mechanism of radical polymerization is preferred.

The molecular weight of the polymer obtained by polymerizing the monomer component can be controlled by appropriately adjusting the amount and type of a polymerization initiator, the polymerization temperature, and the type and amount of a chain transfer agent.

Examples of the polymerization initiator include organic peroxides such as di-t-butyl peroxide and t-butylperoxy-2-ethylhexanoate, and azo compounds such as 2,2′-azobis(isobutyronitrile) and dimethyl 2,2′-azobis(2-methylpropionate), which are commonly used as polymerization initiators. These may be used alone or in combination of two or more.

Examples of the chain transfer agent include compounds having a mercapto group, such as alkyl mercaptans (e.g., n-dodecyl mercaptan), mercaptocarboxylic acids (e.g., 3-mercaptopropionic acid and mercaptoacetic acid), mercaptocarboxylic acid esters (e.g., methyl mercaptoacetate), and hydroxy group-containing mercaptans (e.g., 1-mercaptoethanol, 1-mercapto-1,1-methanediol, 1-mercapto-1,1-ethanediol, 3-mercapto-1,2-propanediol, 2-mercapto-1,2-propanediol, 2-mercapto-2-methyl-1,3-propanediol, 2-mercapto-2-ethyl-1,3-propanediol, 1-mercapto-2,2-propanediol, 2-mercaptoethyl-2-methyl-1,3-propanediol, and 2-mercaptoethyl-2-ethyl-1,3-propanediol), which are commonly used as chain transfer agents. These may be used alone or in combination of two or more. The amounts of these additives can be appropriately set according to known methods. In particular, the chain transfer agent preferably includes at least one selected from the group consisting of the hydroxy group-containing mercaptans and mercaptocarboxylic acids, and more preferably includes a hydroxy group-containing mercaptan and a mercaptocarboxylic acid.

It is believed that use of the hydroxy group-containing mercaptan allows the polymer molecules to have hydroxy groups at their chain ends. The interactions via the hydroxy groups (hydrogen bonds) reduce the degree of freedom of movement of the chain ends while maintaining good alkaline developability. Thereby, a cured product with improved thermomechanical properties can be obtained by curing the polymer. The hydroxy-containing mercaptans are more preferably mercaptans having a plurality of hydroxy groups. The number of hydroxy groups in each hydroxy-containing mercaptan is preferably 2 to 7, more preferably 2 to 5, still more preferably 2 or 3 per molecule.

Examples of a solvent used in the polymerization include ether solvents such as tetrahydrofuran, dioxane, ethylene glycol dimethyl ether, and diethylene glycol dimethyl ether; ketone solvents such as acetone and methyl ethyl ketone; ester solvents such as ethyl acetate, butyl acetate, propylene glycol monomethyl ether acetate, and 3-methoxybutyl acetate; aromatic hydrocarbon solvents such as toluene, xylene, and ethylbenzene; chloroform; dimethyl sulfoxide; and dimethyl carbonate. These solvents may be used alone or in combination of two or more. Of these, the polymerization solvent preferably includes an ester solvent because imide monomers and the resist polymer obtained by polymerization are highly soluble in such a polymerization solvent.

The polymerization solvent preferably contains an ester solvent in an amount of 10 to 100% by mass, more preferably 50 to 100% by mass, still more preferably 80 to 100% by mass, in 100% by mass of the entire polymerization solvent.

Regarding the polymerization conditions, the polymerization temperature may be appropriately set depending on the types and amounts of the monomers used, the type and amount of the polymerization initiator, and the like, and is preferably 50° C. to 130° C., more preferably 60° C. to 120° C., for example. The polymerization time may also be appropriately set as in the above, and is preferably 1 to 5 hours, more preferably 2 to 4 hours, for example.

The method for producing a resist polymer includes a step (1) of polymerizing a monomer component in the presence of a solvent. The monomer component includes a maleimide-based monomer (a), an aromatic monomer (b), and an acid group-containing monomer (c), and the amount of a primary hydroxy group-containing monomer (d) in the monomer component is less than 5% by mass.

Preferably, the monomer component includes a maleimide-based monomer (a) in an amount of 35 to 60% by mass, an aromatic monomer (b) in an amount of 10 to 60% by mass, and an acid group-containing monomer (c) in an amount of 5 to 30% by mass, in 100% by mass of the monomer component, and the amount of a primary hydroxy group-containing monomer (d) in 100% by mass of the monomer component is less than 5% by mass.

More preferably, the monomer component includes a maleimide-based monomer (a) in an amount of 40 to 55% by mass, an aromatic monomer (b) in an amount of 20 to 50% by mass, and an acid group-containing monomer (c) in an amount of 10 to 25% by mass, in 100% by mass of the monomer component, and the amount of a primary hydroxy group-containing monomer (d) in 100% by mass of the monomer component is less than 4% by mass. Still more preferably, the monomer component includes a maleimide-based monomer (a) in an amount of 45 to 50% by mass, an aromatic monomer (b) in an amount of 30 to 40% by mass, and an acid group-containing monomer (c) in an amount of 15 to 20% by mass, in 100% by mass of the monomer component, and the amount of a primary hydroxy group-containing monomer (d) in 100% by mass of the monomer component is less than 3.5% by mass.

Examples of each of the maleimide-based monomer (a), aromatic monomer (b), acid group-containing monomer (c), and primary hydroxy group-containing monomer (d) include those described above.

To provide the resist polymer containing the structural unit (E), the method preferably further includes a step (2) of reacting the polymer obtained in the step (1) as a base polymer with an epoxy group-containing monomer. In the step (2), an acid group of the base polymer is reacted with an epoxy group of the epoxy group-containing monomer to introduce a polymerizable double bond into a side chain of the base polymer.

Examples of the epoxy group-containing monomer include those described above. The amount of the epoxy group-containing monomer relative to the amount of the base polymer is not limited, and may be appropriately adjusted so that the amount of the structural unit (E) falls within a desired range.

In the reaction step (2), commonly used additives such as a polymerization inhibitor and a reaction catalyst may be used. The amounts of the additives may be appropriately adjusted.

Examples of the polymerization inhibitor include benzoquinone, hydroquinones (e.g., hydroquinone, hydroquinone monomethyl ether, p-tert-butylhydroquinone, p-benzoquinone), phenols (e.g., 2,6-di-t-butyl-4-methylphenol, 6-t-butyl-2,4-dimethylphenol, 2,2′-methylenebis(4-methyl-6-t-butylphenol)), catechols (e.g., p-tert-butylcatechol), amines (e.g., N,N-diethylhydroxylamine), 1,1-diphenyl-2-picrylhydrazyl, tri-p-nitrophenylmethyl, phenothiazine, piperidine-1-oxyls (e.g., 2,2,6,6-tetramethylpiperidine-1-oxyl), and oxygen.

Examples of the reaction catalyst include tertiary amines such as triethylamine, tertiary phosphines such as triphenylphosphine, lithium chloride, quaternary ammonium salts, and quaternary phosphonium salts. Of these, tertiary amines and tertiary phosphines are preferred because they increase the electrical insulation properties of the cured product.

In the reaction step (2), the reaction temperature is preferably, but not limited to, 90° C. to 140° C., more preferably 100° C. to 130° C., still more preferably 110° C. to 120° C. The reaction time is preferably, but not limited to, 2 to 20 hours, more preferably 3 to 15 hours, still more preferably 5 to 10 hours.

The method for producing a resist polymer may include a step different from the steps described above. Examples of the different step include an aging step, a neutralization step, a step of deactivating a polymerization initiator or a chain transfer agent, a dilution step, a drying step, a concentration step, and a purification step. These steps can be performed by known methods.

The present disclosure also encompasses such a method for producing a polymer as described above, the method including polymerizing a monomer component in the presence of a solvent. The monomer component includes a maleimide-based monomer (a) in an amount of 35 to 60% by mass, an aromatic monomer (b) in an amount of 10 to 60% by mass, and an acid group-containing monomer (c) in an amount of 5 to 30% by mass, in 100% by mass of the monomer component; the amount of a primary hydroxy group-containing monomer (d) in 100% by mass of the monomer component is less than 5% by mass; and the solvent includes an ester solvent. The polymerization step is preferably carried out in the presence of a polymerization initiator and a chain transfer agent in addition to the solvent.

### 2. Photosensitive Resin Composition

The resist polymer of the present disclosure can be combined with an organic solvent to form a photosensitive resin composition. The present disclosure also encompasses such a photosensitive resin composition containing the resist polymer and an organic solvent. The photosensitive resin composition of the present disclosure containing the resist polymer is excellent in photocurability and alkali solubility, and can provide a cured product excellent in heat resistance, moisture resistance, and thermomechanical properties.

The photosensitive resin composition may contain any amount of the resist polymer. The amount of the resist polymer may be appropriately set depending on the application, other components to be added, and the like. For example, the amount of the resist polymer is preferably 5 to 90% by mass, more preferably 10 to 85% by mass, still more preferably 15 to 80% by mass, based on 100% by mass of the total amount of solids in the photosensitive resin composition.

Herein, the total amount of solids means the total amount of components that form a cured product (excluding components that volatilize during formation of the cured product, such as solvents).

The organic solvent may be any solvent and appropriately selected depending on the purpose and application. Examples of the organic solvent include the above-described polymerization solvents and other known solvents.

The amount of the organic solvent is not limited and may be appropriately adjusted depending on the application of the photosensitive resin composition and the like. The amount is preferably 10 to 90% by mass, more preferably 15 to 85% by mass, still more preferably 20 to 80% by mass, relative to 100% by mass of the solids (total amount) in the photosensitive resin composition.

The photosensitive resin composition preferably further contains a thermal crosslinking agent. The presence of a thermal crosslinking agent improves the crosslink density of the cured product, thereby further improving its moisture resistance, heat resistance, and thermomechanical properties.

The thermal crosslinking agent is preferably a compound having a group capable of reacting with an acid group such as a carboxy group, and examples thereof include epoxy compounds, melamine compounds, and oxazoline compounds. Of these, epoxy compounds are preferred because they are excellent in photocurability and can impart excellent resolution during image formation.

The amount of the thermal crosslinking agent is not limited and may be appropriately adjusted depending on the application of the photosensitive resin composition and the like. The amount is preferably, for example, 1 to 40% by mass, more preferably 1.5 to 35% by mass, still more preferably 2 to 30% by mass, based on 100% by mass of the solids (total amount) in the photosensitive resin composition.

The photosensitive resin composition preferably further contains a photoinitiator and a polymerizable compound.

The photoinitiator may preferably be a radically polymerizable photoinitiator.

Specific examples of the photoinitiator include aminoketone compounds such as 2-methyl-1-[4-(methylthio)phenyl]-2-morpholinopropan-1-one (“Irgacure 907”, available from BASF), 2-benzyl-2-dimethylamino-1-(4-morpholinophenyl)-butanone-1 (“Irgacure 369”, available from BASF), and 2-dimethylamino-2-(4-methyl-benzyl)-1-(4-morpholin-4-yl-phenyl)-butan-1-one (“Irgacure 379”, available from BASF); benzyl ketal compounds such as 2,2-dimethoxy-1,2-diphenylethan-1-one (“Irgacure 651”, available from BASF) and phenylglyoxylic acid methyl ester (“Darocur MBF, available from BASF); hydroketone compounds such as 1-hydroxy-cyclohexyl-phenyl-ketone (“Irgacure 184”, available from BASF), 2-hydroxy-2-methyl-1-phenyl-propan-1-one (“Darocur 1173”, available from BASF), 1-[4-(2-hydroxyethoxy)-phenyl]-2-hydroxy-2-methyl-1-propan-1-one (“Irgacure 2959”, available from BASF), 2-hydroxy-1-{4-[4-(2-hydroxy-2-methyl-propionyl)-benzyl]-phenyl}-2-methyl-propan-1-one (“Irgacure 127”, available from BASF), and [1-hydroxy-cyclohexyl-phenyl-ketone+benzophenone](“Irgacure 500”, available from BASF); other alkylphenone compounds exemplified in paragraphs [0084] to [0086] of JP 2013-227485 A; oxime ester compounds such as 1,2-octanedione, 1-[4-(phenylthio)phenyl]-, 2-(O-benzoyloxime) (“OXE01”, available from BASF), ethanone, 1-[9-ethyl-6-(2-methylbenzoyl)-9H-carbazol-3-yl]-, 1-(0-acetyloxime) (“OXE02”, available from BASF), 1,2-octanedione, 1-[4-(phenylthio)-, 2-, (O-benzoyloxime)], ethanone (“OXE03”, available from BASF), and 1-[9-ethyl-6-(2-methylbenzoyl)-9H-carbazol-3-yl]-, 1-(0-acetyloxime) (“OXE04”, available from BASF); benzophenone compounds; benzoin compounds; thioxanthone compounds; halomethylated triazine compounds; halomethylated oxadiazole compounds; biimidazole compounds; titanocene compounds; benzoic acid ester compounds; acridine compounds; and phosphine oxide compounds. These may be used alone or in combination of two or more.

The amount of the photoinitiator is not limited as long as it is within a range in which the effects of the present disclosure can be achieved, and may be appropriately set. For example, the amount is preferably 0.5 to 30% by mass, more preferably 0.7 to 25% by mass, still more preferably 1 to 20% by mass, based on 100% by mass of the total amount of solids in the photosensitive resin composition of the present disclosure.

The polymerizable compound may be a low molecular compound having a polymerizable unsaturated bond (also referred to as a polymerizable unsaturated group), which can polymerize by free radicals or by irradiation with active energy rays such as electromagnetic waves (e.g., infrared rays, ultraviolet rays, X-rays) or electron beams. Examples of the polymerizable compound include a monofunctional compound having one polymerizable unsaturated group in the molecule and a polyfunctional compound having two or more polymerizable unsaturated groups in the molecule.

Examples of the monofunctional compound include N-substituted maleimide-based monomers; (meth)acrylic acid esters; (meth)acrylamides; unsaturated monocarboxylic acids; unsaturated polycarboxylic acids; unsaturated monocarboxylic acids having an extended chain between the unsaturated group and the carboxy group; unsaturated acid anhydrides; aromatic vinyl compounds; conjugated dienes; vinyl esters; vinyl ethers; N-vinyl compounds; and unsaturated isocyanates. Furthermore, monomers having an active methylene group or an active methine group can also be used, for example.

Examples of the polyfunctional compound are listed as follows: ethylene glycol di(meth)acrylate, diethylene glycol di(meth)acrylate, polyethylene glycol di(meth)acrylate, propylene glycol di(meth)acrylate, butylene glycol di(meth)acrylate, hexanediol di(meth)acrylate, cyclohexanedimethanol di(meth)acrylate, bisphenol A alkylene oxide di(meth)acrylates, bisphenol F alkylene oxide di(meth)acrylates, and other bifunctional (meth)acrylate compounds; trimethylolpropane tri(meth)acrylate, ditrimethylolpropane tetra(meth)acrylate, glycerol tri(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, ethylene oxide-added trimethylolpropane tri(meth)acrylate, ethylene oxide-added ditrimethylolpropane tetra(meth)acrylate, ethylene oxide-added pentaerythritol tetra(meth)acrylate, ethylene oxide-added dipentaerythritol hexa(meth)acrylate, propylene oxide-added trimethylolpropane tri(meth)acrylate, propylene oxide-added ditrimethylolpropane tetra(meth)acrylate, propylene oxide-added pentaerythritol tetra(meth)acrylate, propylene oxide-added dipentaerythritol hexa(meth)acrylate, E-caprolactone-added trimethylolpropane tri(meth)acrylate, E-caprolactone-added ditrimethylolpropane tetra(meth)acrylate, F-caprolactone-added pentaerythritol tetra(meth)acrylate, F-caprolactone-added dipentaerythritol hexa(meth)acrylate, a succinic acid-modified dipentaerythritol pentaacrylate, a succinic acid-modified pentaerythritol triacrylate, a phthalic acid-modified dipentaerythritol pentaacrylate, a phthalic acid-modified pentaerythritol triacrylate, a modified dipentaerythritol hexaacrylate represented by the following formula (6):

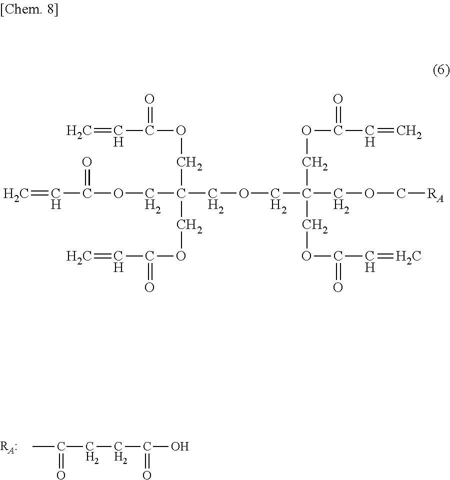

and other tri- or higher functional (meth)acrylate compounds;
ethylene glycol divinyl ether, diethylene glycol divinyl ether, polyethylene glycol divinyl ether, propylene glycol divinyl ether, butylene glycol divinyl ether, hexanediol divinyl ether, bisphenol A alkylene oxide divinyl ethers, bisphenol F alkylene oxide divinyl ethers, trimethylolpropane trivinyl ether, ditrimethylolpropane tetravinyl ether, glycerol trivinyl ether, pentaerythritol tetravinyl ether, dipentaerythritol pentavinyl ether, dipentaerythritol hexavinyl ether, ethylene oxide-added trimethylolpropane trivinyl ether, ethylene oxide-added ditrimethylolpropane tetravinyl ether, ethylene oxide-added pentaerythritol tetravinyl ether, ethylene oxide-added dipentaerythritol hexavinyl ether, and other polyfunctional vinyl ethers;
2-vinyloxyethyl (meth)acrylate, 3-vinyloxypropyl (meth)acrylate, 1-methyl-2-vinyloxyethyl (meth)acrylate, 2-vinyloxypropyl (meth)acrylate, 4-vinyloxybutyl (meth)acrylate, 4-vinyloxycyclohexyl (meth)acrylate, 5-vinyloxypentyl (meth)acrylate, 6-vinyloxyhexyl (meth)acrylate, 4-vinyloxymethylcyclohexylmethyl (meth)acrylate, p-vinyloxymethylphenylmethyl (meth)acrylate, 2-(vinyloxyethoxy)ethyl (meth)acrylate, 2-(vinyloxyethoxyethoxyethoxy)ethyl (meth)acrylate, and other vinyl ether group-containing (meth)acrylic acid esters;
ethylene glycol diallyl ether, diethylene glycol diallyl ether, polyethylene glycol diallyl ether, propylene glycol diallyl ether, butylene glycol diallyl ether, hexanediol diallyl ether, bisphenol A alkylene oxide diallyl ethers, bisphenol F alkylene oxide diallyl ethers, trimethylolpropane triallyl ether, ditrimethylolpropane tetraallyl ether, glycerol triallyl ether, pentaerythritol tetraallyl ether, dipentaerythritol pentaallyl ether, dipentaerythritol hexaallyl ether, ethylene oxide-added trimethylolpropane triallyl ether, ethylene oxide-added ditrimethylolpropane tetraallyl ether, ethylene oxide-added pentaerythritol tetraallyl ether, ethylene oxide-added dipentaerythritol hexaallyl ether, and other polyfunctional allyl ethers;
allyl (meth)acrylate and other allyl group-containing (meth)acrylic acid esters; tri(acryloyloxyethyl)isocyanurate, tri(methacryloyloxyethyl)isocyanurate, alkylene oxide-added tri(acryloyloxyethyl)isocyanurates, alkylene oxide-added tri(methacryloyloxyethyl)isocyanurates, and other polyfunctional (meth)acryloyl group-containing isocyanurates; triallyl isocyanurate and other polyfunctional allyl group-containing isocyanurates; polyfunctional urethane (meth)acrylates obtained by reacting a polyfunctional isocyanate (e.g., tolylene diisocyanate, isophorone diisocyanate, or xylylene diisocyanate) with a hydroxy group-containing (meth)acrylic acid ester (e.g., 2-hydroxyethyl (meth)acrylate or 2-hydroxypropyl (meth)acrylate); and divinylbenzene and other polyfunctional aromatic vinyl compounds. These polymerizable compounds may be used alone or in combination of two or more.

The amount of the polymerizable compound is not limited as long as it is within a range in which the effects of the present disclosure are exhibited, and may be appropriately set. For example, the amount is preferably 5 to 80% by mass, more preferably 7 to 70% by mass, still more preferably 9 to 50% by mass, based on 100% by mass of the total amount of solids in the photosensitive resin composition of the present disclosure.

The photosensitive resin composition may optionally contain a component different from the above-described components. Examples of the different component include colorants (pigments, dyes); dispersants; heat resistance improvers; leveling agents; developing aids; inorganic fine particles such as silica fine particles and zirconia fine particles; coupling agents such as silane coupling agents, aluminum coupling agents, and titanium coupling agents; thermosetting resins such as phenolic resins and polyvinylphenols; curing aids such as polyfunctional thiol compounds; plasticizers; polymerization inhibitors; ultraviolet absorbers; antioxidants; matting agents; defoaming agents; antistatic agents; slip agents; surface modifiers; thixotropic agents; thixotropic aids; quinone diazide compounds; polyhydric phenol compounds; cationic polymerizable compounds; and acid generators. These may be used alone or in combination of two or more. These different components may be appropriately selected from known components, and the amounts thereof may be appropriately set.

### <Preparation of Photosensitive Resin Composition>

The photosensitive resin composition of the present disclosure may be prepared by any method including known methods. For example, the components may be mixed and dispersed using any of various mixers or dispersers. The mixing and dispersing may be carried out by any known method. The preparation method may further include a different commonly used step. To provide the photosensitive resin composition containing a coloring material, the photosensitive resin composition is preferably prepared through dispersion treatment of a coloring material or other known steps.

### <Cured Product>

A cured product produced by curing the photosensitive resin composition of the present disclosure is excellent in heat resistance, moisture resistance, and thermomechanical properties.

The cured product may be produced by any method including known methods. For example, the photosensitive resin composition is molded or applied to a substrate, and then cured by drying, heating, or exposure to energy rays such as ultraviolet rays or by a combination of these to obtain the cured product.

The cured product may also be produced as follows: the photosensitive resin composition is applied to a substrate by a known method; the applied composition is optionally dried to form a coating film; the coating film is then exposed to light through a photomask; after the exposure, the unexposed portions are dissolved in an aqueous alkaline solution for alkaline development; the workpiece is optionally washed; and heating (post-curing) is performed. The coating, drying, exposure, alkaline development, and heating may be carried out by a known techniques.

When the cured product is a cured film, the cured film preferably has a film thickness of 0.5 to 10 μm, more preferably 0.7 to 7 μm, still more preferably 1 to 5 μm, in order to ensure good heat resistance and thermomechanical properties.

### 3. Applications

The resist polymer and photosensitive resin composition of the present disclosure are excellent in photocurability and alkali solubility, and can provide a cured product excellent in heat resistance, moisture resistance, and thermomechanical properties. Therefore, they are suitable for use in resist applications requiring photocurability, alkali solubility, heat resistance, moisture resistance, or thermomechanical properties.

Specific preferred applications of the resist polymer and photosensitive resin composition of the present disclosure include applications for various optical components and components of devices such as electric/electronic devices. Examples of these components include color filters, black matrices, photo spacers, black column spacers, inks, printing plates, printed wiring boards, semiconductor elements, photoresists, films, and organic insulating films (interlayer insulating films), which are for use in liquid crystal, organic EL, quantum dot, or micro LED liquid crystal displays, solid-state image sensors, touch panel display devices, and millimeter wave antennas. Of these, the resist polymer and photosensitive resin composition of the present disclosure are suitable for an interlayer insulating film application because they can impart good thermomechanical properties.

Examples of an interlayer insulating film include: an insulating film formed between a TFT array element and a transparent conductive film that forms a pixel electrode in a TFT active matrix substrate used in a liquid crystal display device in order to protect the TFT array element; and an insulating film formed between a semiconductor chip and a conductive line layer. The present disclosure also encompasses such an interlayer insulating film made of a cured product of the photosensitive resin composition.

### EXAMPLES

The present disclosure is described in more detail below with reference to examples, but is not limited to these examples. It should be noted that the terms “part(s)” and “%” refer to “part(s) by mass” and “% by mass”, respectively, unless otherwise stated.

In the examples, the physical properties were measured as follows.

### <Acid Value>

About 3 g of a polymer solution was precisely weighed out and dissolved in a solvent mixture of 90 g of acetone and 10 g of water, and the resulting solution was titrated using a 0.1 N aqueous KOH solution as a titrant. The titration was performed using an automatic titrator (trade name: COM-555, available from HIRANUMA Co., Ltd.), and the acid value per gram of solids (mg KOH/g) was calculated from the acid value of the polymer solution and the amount of solids in the polymer solution. The amount of solids in the polymer solution was determined by the following method. Specifically, about 1 g of the polymer solution was precisely weighed out in an aluminum cup and dissolved with about 3 g of acetone added thereto, and the resulting solution was then naturally dried at room temperature. Then, the resulting sample was dried at 160° C. for 1.5 hours using a vacuum dryer (trade name: VOS-301SD, available from EYELA TOKYO RIKAKIKAI CO., LTD.), and then cooled in a desiccator. The mass of the resulting sample was measured. The mass loss was determined and the amount of solids (% by mass) in the polymer solution was calculated therefrom.

<Double Bond Equivalent Weight (g/Eq)>

The double bond equivalent weight was determined by dividing the mass (g) of solids in the polymer solution by the amount (mol) of double bonds in the polymer. The amount of double bonds was determined by dividing the mass of each compound having a polymerizable double bond used for introducing a polymerizable double bond by the molecular weight of the compound.

<Ester Bond Equivalent Weight (g/Eq)>

The ester bond equivalent weight was determined by dividing the mass (g) of solids in the polymer solution by the amount (mol) of ester bonds in the polymer. The amount of ester bonds was calculated as the sum of the following values: values each determined by dividing the mass of a compound having an ester bond among the monomers used in the polymer synthesis by the molecular weight of the compound; and in the case where ester bonds were generated in a reaction for introducing polymerizable double bonds, values each determined by dividing the mass of a compound having a polymerizable double bond used for introduction of a polymerizable double bond by the molecular weight of the compound.

<Imide Equivalent Weight (g/Eq)>

The imide equivalent weight was determined by dividing the mass (g) of solids in the polymer solution by the amount (mol) of imide groups in the polymer. The amount of imide groups was determined by dividing the mass of each compound having an imide group among the monomers used in the polymer synthesis by the molecular weight of the compound.

### <Weight Average Molecular Weight>

The weight average molecular weight was determined by gel permeation chromatography (GPC) using an HLC-8220GPC (Tosoh Corporation), with polystyrene as the standard substance and tetrahydrofuran as the eluent.

### <Thermal Decomposition Resistance>

A solution prepared by adding 4 g of tetrahydrofuran to 2 g of a polymer solution was added dropwise to 60 g of hexane, and the precipitated polymer was separated and dried in vacuum at 40° C. overnight. A 10-mg portion of the obtained polymer powder was subjected to measurement of a 5% weight loss temperature using a thermogravimetric analyzer TGA-50 (Shimadzu Corporation) in a nitrogen atmosphere. The higher the 5% weight loss temperature, the higher the thermal decomposition resistance.

### <Alkali Solubility>

To a polymer solution were added dipentaerythritol hexaacrylate (DPHA) and a photoinitiator (Irgacure 907, available from BASF) in amounts of 30% and 5%, respectively, of the solids in the polymer solution. The resulting solution was mixed with propylene glycol monomethyl ether acetate (PGMEA) to prepare a solution with a percentage of the resin solids of 30%. The resulting solution was applied to a copper plate (50 mm long×50 mm wide) by spin coating, dried at 80° C. for 30 minutes, and then cooled to room temperature to prepare a test plate for evaluation on which a coating film having a thickness of 4 μm was formed. The prepared test plate was immersed in a 1% by mass aqueous sodium carbonate solution at 30° C. for 30 or 60 seconds, and the degree of residual coating film after dissolution was visually observed to evaluate the alkali solubility.

### <Photocurability>

The test plate for alkali solubility evaluation obtained above was irradiated with light of 2 J/cm², and then immersed in a 1% by mass aqueous sodium carbonate solution at 30° C. for 60 seconds. When no whitening or erosion of the coating film was observed, the test plate was rated as “good”.

<Moisture Resistance (Adhesion after PCT Treatment)>

A peel test was performed after pressure cooker test (PCT) treatment, and the moisture resistance was evaluated. First, a dry coating film was formed in the same manner as in the evaluation of photocurability, and then irradiated with light to obtain a cured product. The cured product was heated at 150° C. for one hour to prepare a test substrate, which was then heated at 120° C. under vapor pressure for six hours. The cured film after heating was subjected to a cross-cut test in accordance with JIS K 5600-5-6:1999 and evaluated according to the following criteria.
◯◯: Grade 0 in the evaluation criteria of JIS K 5600-5-6:1999.
◯: Grade 1 in the evaluation criteria of JIS K 5600-5-6:1999.
Δ: Grade 2 in the evaluation criteria of JIS K 5600-5-6:1999.
x: Grade 3 in the evaluation criteria of JIS K 5600-5-6:1999.

A cross-cut test was also conducted on each cured film before the PCT treatment, and all the results were rated as oo.

### <Thermomechanical Properties (TMA)>

According to the ratios shown in Table 2, to a polymer solution were added 828EL (bisphenol A epoxy resin available from Mitsubishi Chemical Corporation, epoxy equivalent weight 186, the number of moles of carboxy groups of the polymer is equal to that of epoxy groups of the epoxy resin) and triphenylphosphine to prepare a thermosetting resin composition. The obtained thermosetting resin composition was applied to a polyethylene terephthalate film so that it would have a thickness after drying of approximately 80 μm, dried at 90° C. for 30 minutes, cured at 180° C. for one hour, and then cooled. The cured coating film was peeled off and cut into a width of 5 mm to prepare a measurement specimen. The specimen was subjected to thermal analysis using a thermomechanical analyzer Bruker AXS TMA 4000 (Bruker AXS Co., Ltd.) in a tensile mode with a chuck distance of 20 mm, and evaluated for thermomechanical properties based on the glass transition temperature (Tg) and the average coefficient of linear expansion a50-150 (ppm/° C.) at 50° C. to 150° C.

### Synthesis Example 1 (Example 1)

A separable flask equipped with a cooling tube serving as a reaction vessel was charged with 100 g of propylene glycol monomethyl ether acetate (PGMEA), purged with nitrogen, and then heated to 90° C. Separately, in a dropping vessel 1, 45 g of N-benzylmaleimide, 18.8 g of acrylic acid, 2 g of t-butylperoxy-2-ethylhexanoate, and 144 g of PGMEA were mixed. In addition, in a dropping vessel 2, 36.2 g of vinyltoluene (a mixture of m-vinyltoluene and p-vinyltoluene at 60:40) and 5 g of 3-mercaptopropionic acid were mixed. While maintaining the reaction temperature at 90° C., the contents in the dropping vessel 1 and the contents in the dropping vessel 2 were each added dropwise to the reaction vessel at a constant rate over four hours. After the dropwise addition was completed, the temperature was maintained at 90° C. for 30 minutes, then 1.5 g of t-butylperoxy-2-ethylhexanoate was added, and the reaction was continued at 90° C. for another 30 minutes. Thereafter, the reaction temperature was raised to 115° C., the reaction was continued for 1.5 hours, and the mixture was cooled to room temperature to obtain a polymer solution A-1. The evaluation results of the property values, 5% weight loss temperature, alkali solubility, photocurability, and moisture resistance (adhesion after PCT treatment) of the resulting polymer are shown in Table 1.

### Synthesis Example 2 (Example 2)

A separable flask equipped with a cooling tube serving as a reaction vessel was charged with 100 g of propylene glycol monomethyl ether acetate (PGMEA), purged with nitrogen, and then heated to 90° C. Separately, in a dropping vessel 1, 45 g of N-benzylmaleimide, 18.8 g of acrylic acid, 2 g of t-butylperoxy-2-ethylhexanoate, and 144 g of PGMEA were mixed. In addition, in a dropping vessel 2, 36.2 g of vinyltoluene (a mixture of m-vinyltoluene and p-vinyltoluene at 60:40) and 5 g of 3-mercaptopropionic acid were mixed. While maintaining the reaction temperature at 90° C., the contents in the dropping vessels 1 and 2 were added dropwise to the reaction vessel at a constant rate over four hours. After the dropwise addition was completed, the temperature was maintained at 90° C. for 30 minutes, then 1.5 g of t-butylperoxy-2-ethylhexanoate was added, and the reaction was continued at 90° C. for another 30 minutes. Thereafter, the reaction temperature was raised to 115° C., and the reaction was continued for 1.5 hours. After the temperature was reduced to room temperature, 9.5 g of glycidyl methacrylate, 0.3 g of Antage W-400 (Kawaguchi Chemical Industry Co., Ltd.) as a polymerization inhibitor, and 0.2 g of triethylamine as a catalyst were added. The temperature was raised to 110° C. while bubbling a nitrogen-air mixed gas adjusted to an oxygen concentration of 7%, and the reaction was carried out for two hours. Thereafter, the temperature was raised to 115° C., the reaction was continued for five hours to complete the reaction, and the mixture was cooled to room temperature to obtain a polymer solution A-2. The evaluation results of the property values, 5% weight loss temperature, alkali solubility, photocurability, and moisture resistance (adhesion after PCT treatment) of the resulting polymer are shown in Table 1.

### Synthesis Example 3 (Example 3)

A separable flask equipped with a cooling tube serving as a reaction vessel was charged with 100 g of propylene glycol monomethyl ether acetate (PGMEA), purged with nitrogen, and then heated to 90° C. Separately, in a dropping vessel 1, 50 g of N-benzylmaleimide, 18.8 g of acrylic acid, 4 g of t-butylperoxy-2-ethylhexanoate, and 141 g of PGMEA were mixed. In addition, a dropping vessel 2 was charged with 31.2 g of vinyltoluene (a mixture of m-vinyltoluene and p-vinyltoluene at 60:40). While maintaining the reaction temperature at 90° C., the contents in the dropping vessels 1 and 2 were added dropwise to the reaction vessel at a constant rate over four hours. After the dropwise addition was completed, the temperature was maintained at 90° C. for 30 minutes, then 3 g of t-butylperoxy-2-ethylhexanoate was added, and the reaction was continued at 90° C. for another 30 minutes. Thereafter, the reaction temperature was raised to 115° C., and the reaction was continued for 1.5 hours. After the temperature was reduced to room temperature, 9.5 g of glycidyl methacrylate, 0.3 g of Antage W-400 (Kawaguchi Chemical Industry Co., Ltd.) as a polymerization inhibitor, and 0.2 g of triethylamine as a catalyst were added. The temperature was raised to 110° C. while bubbling a nitrogen-air mixed gas adjusted to an oxygen concentration of 7%, and the reaction was carried out for two hours. Thereafter, the temperature was raised to 115° C., the reaction was continued for five hours to complete the reaction, and the mixture was cooled to room temperature to obtain a polymer solution A-3. The evaluation results of the property values, 5% weight loss temperature, alkali solubility, photocurability, and moisture resistance (adhesion after PCT treatment) of the resulting resin are shown in Table 1.

### Synthesis Example 4 (Example 4)

A polymer solution A-4 was obtained as in Synthesis Example 2, except that N-phenylmaleimide was used instead of N-benzylmaleimide. The evaluation results of the property values, 5% weight loss temperature, alkali solubility, photocurability, and moisture resistance (adhesion after PCT treatment) of the resulting resin are shown in Table 1.

### Synthesis Example 5 (Example 5)

A polymer solution A-5 was obtained as in Synthesis Example 2, except that styrene was used instead of vinyltoluene. The evaluation results of the property values, 5% weight loss temperature, alkali solubility, photocurability, and moisture resistance (adhesion after PCT treatment) of the resulting resin are shown in Table 1.

### Synthesis Example 6 (Example 6)

A polymer solution A-6 was obtained as in Synthesis Example 2, except that a mixture of 33.2 g of vinyltoluene and 3 g of 2-hydroxyethyl methacrylate was used instead of 36.2 g of vinyltoluene. The evaluation results of the property values, 5% weight loss temperature, alkali solubility, photocurability, and moisture resistance (adhesion after PCT treatment) of the resulting resin are shown in Table 1.

### Synthesis Example 7 (Example 7)

A separable flask equipped with a cooling tube serving as a reaction vessel was charged with 100 g of PGMEA, purged with nitrogen, and then heated to 90° C. Separately, in a dropping vessel 1, 35 g of N-benzylmaleimide, 24 g of acrylic acid, 2 g of t-butylperoxy-2-ethylhexanoate, and 144 g of PGMEA were mixed. In addition, in a dropping vessel 2, 41 g of vinyltoluene (a mixture of m-vinyltoluene and p-vinyltoluene at 60:40) and 5 g of 3-mercaptopropionic acid were mixed. While maintaining the reaction temperature at 90° C., the contents in the dropping vessels 1 and 2 were added dropwise to the reaction vessel at a constant rate over four hours. After the dropwise addition was completed, the temperature was maintained at 90° C. for 30 minutes, then 1.5 g of t-butylperoxy-2-ethylhexanoate was added, and the reaction was continued at 90° C. for another 30 minutes. Thereafter, the reaction temperature was raised to 115° C., and the reaction was continued for 1.5 hours. After the temperature was reduced to room temperature, 17.4 g of glycidyl methacrylate, 0.3 g of Antage W-400 (Kawaguchi Chemical Industry Co., Ltd.) as a polymerization inhibitor, and 0.2 g of triethylamine as a catalyst were added. The temperature was raised to 110° C. while bubbling a nitrogen-air mixed gas adjusted to an oxygen concentration of 7%, and the reaction was carried out for two hours. Thereafter, the temperature was raised to 115° C., the reaction was continued for nine hours to complete the reaction, and the mixture was cooled to room temperature to obtain a polymer solution A-7. The evaluation results of the property values, 5% weight loss temperature, alkali solubility, photocurability, and moisture resistance (adhesion after PCT treatment) of the resulting resin are shown in Table 1.

### Synthesis Example 8 (Example 8)

A separable flask equipped with a cooling tube serving as a reaction vessel was charged with 100 g of propylene glycol monomethyl ether acetate (PGMEA), purged with nitrogen, and then heated to 90° C. Separately, in a dropping vessel 1, 45 g of N-benzylmaleimide, 20 g of acrylic acid, 2 g of t-butylperoxy-2-ethylhexanoate, and 144 g of PGMEA were mixed. In addition, in a dropping vessel 2, 35 g of vinyltoluene (a mixture of m-vinyltoluene and p-vinyltoluene at 60:40), 2.2 g of 3-mercaptopropionic acid, and 1.1 g of 3-mercapto-1,2-propanediol were mixed. While maintaining the reaction temperature at 90° C., the contents in the dropping vessels 1 and 2 were added dropwise to the reaction vessel at a constant rate over four hours. After the dropwise addition was completed, the temperature was maintained at 90° C. for 30 minutes, then 0.6 g of t-butylperoxy-2-ethylhexanoate was added, and the reaction was continued at 90° C. for another 30 minutes. Thereafter, the reaction temperature was raised to 115° C., and the reaction was continued for 1.5 hours. After the temperature was reduced to room temperature, 9.5 g of glycidyl methacrylate, 0.3 g of Antage W-400 (Kawaguchi Chemical Industry Co., Ltd.) as a polymerization inhibitor, and 0.2 g of triethylamine as a catalyst were added. The temperature was raised to 110° C. while bubbling a nitrogen-air mixed gas adjusted to an oxygen concentration of 7%, and the reaction was carried out for two hours. Thereafter, the temperature was raised to 115° C., the reaction was continued for five hours to complete the reaction, and the mixture was cooled to room temperature to obtain a polymer solution A-8. The evaluation results of the property values, 5% weight loss temperature, alkali solubility, photocurability, and moisture resistance (adhesion after PCT treatment) of the resulting polymer are shown in Table 1.

### Synthesis Example 9 (Comparative Example 1)

A comparative polymer solution B-1 was obtained as in Synthesis Example 1, except that the amount of N-benzylmaleimide was 25 g and the amount of vinyltoluene (a mixture of m-vinyltoluene and p-vinyltoluene at 60:40) was 56.2 g. The evaluation results of the property values, 5% weight loss temperature, alkali solubility, photocurability, and moisture resistance (adhesion after PCT treatment) of the resulting resin are shown in Table 1.

### Synthesis Example 10 (Comparative Example 2)

A comparative polymer solution B-2 was obtained as in Synthesis Example 2, except that the amount of N-benzylmaleimide was 30 g and the amount of vinyltoluene (a mixture of m-vinyltoluene and p-vinyltoluene at 60:40) was 51.2 g. The evaluation results of the property values, 5% weight loss temperature, alkali solubility, photocurability, and moisture resistance (adhesion after PCT treatment) of the resulting resin are shown in Table 1.

### Synthesis Example 11 (Comparative Example 3)

A separable flask equipped with a cooling tube serving as a reaction vessel was charged with 100 g of PGMEA, purged with nitrogen, and then heated to 90° C. Separately, in a dropping vessel 1, 30 g of N-benzylmaleimide, 24 g of acrylic acid, 2 g of t-butylperoxy-2-ethylhexanoate, and 144 g of PGMEA were mixed. In addition, in a dropping vessel 2, 46 g of vinyltoluene (a mixture of m-vinyltoluene and p-vinyltoluene at 60:40) and 5 g of 3-mercaptopropionic acid were mixed. While maintaining the reaction temperature at 90° C., the contents in the dropping vessels 1 and 2 were added dropwise to the reaction vessel at a constant rate over four hours. After the dropwise addition was completed, the temperature was maintained at 90° C. for 30 minutes, then 1.5 g of t-butylperoxy-2-ethylhexanoate was added, and the reaction was continued at 90° C. for another 30 minutes. Thereafter, the reaction temperature was raised to 115° C., and the reaction was continued for 1.5 hours. After the temperature was reduced to room temperature, 17.4 g of glycidyl methacrylate, 0.3 g of Antage W-400 (Kawaguchi Chemical Industry Co., Ltd.) as a polymerization inhibitor, and 0.2 g of triethylamine as a catalyst were added. The temperature was raised to 110° C. while bubbling a nitrogen-air mixed gas adjusted to an oxygen concentration of 7%, and the reaction was carried out for two hours. Thereafter, the temperature was raised to 115° C., the reaction was continued for nine hours to complete the reaction, and the mixture was cooled to room temperature to obtain a comparative polymer solution B-3. The evaluation results of the property values, 5% weight loss temperature, alkali solubility, photocurability, and moisture resistance (adhesion after PCT treatment) of the resulting resin are shown in Table 1.

### Synthesis Example 12 (Comparative Example 4)

A comparative polymer solution B-4 was obtained as in Synthesis Example 2, except that a mixture of 31.2 g of vinyltoluene and 5 g of 2-hydroxyethyl methacrylate was used instead of 36.2 g of vinyltoluene. The evaluation results of the property values, 5% weight loss temperature, alkali solubility, photocurability, and moisture resistance (adhesion after PCT treatment) of the resulting resin are shown in Table 1.

### Examples 9 to 16 and Comparative Examples 5 to 8

Table 2 shows the results of thermomechanical property (TMA) measurements. The values of A-1 to A-8 and B-1 to B-4 in Table 2 are the amounts of resin solids.

TABLE 1

| | | Exam- | Exam- | Exam- | Exam- | Exam- | Exam- | Exam- |
|---|---|---|---|---|---|---|---|---|
| | | ple | ple | ple | ple | ple | ple | ple |
| | | 1 | 2 | 3 | 4 | 5 | 6 | 7 |
| Polymer solution | | A-1 | A-2 | A-3 | A-4 | A-5 | A-6 | A-7 |
| Polymerization | N-benzylmaleimide | 45 | 45 | 50 | — | 45 | 45 | 35 |
| step | N-phenylmaleimide | — | — | — | 45 | — | — | — |
| | Acrylic acid | 18.8 | 18.8 | 18.8 | 18.8 | 18.8 | 18.8 | 24 |
| | Vinyl toluene | 36.2 | 36.2 | 31.2 | 36.2 | — | 33.2 | 41 |
| | Styrene | — | — | — | — | 36.2 | — | — |
| | 2-Hydroxyethyl | — | — | — | — | — | 3 | — |
| | methacrylate | | | | | | | |
| | 3-Mercaptopropionic | 5 | 5 | — | 5 | 5 | 5 | 5 |
| | acid | | | | | | | |
| | 3-Mercapto-1,2- | — | — | — | — | — | — | — |
| | propanediol | | | | | | | |
| Additional | Glycidyl | — | 9.5 | 9.5 | 9.5 | 9.5 | 9.5 | 17.4 |
| step | methacrylate | | | | | | | |
| Acid value (mgKOH/g) | | 165 | 121 | 102 | 122 | 122 | 120 | 121 |
| Double bond equivalent (g/eq) | | None | 1710 | 1640 | 1710 | 1710 | 1710 | 1000 |
| Ester bond equivalent (g/eq) | | None | 860 | 820 | 860 | 860 | 730 | 500 |
| Imide equivalent (g/eq) | | 440 | 480 | 410 | 440 | 480 | 480 | 650 |
| Weight average molecular weight (Mw) | | 5100 | 5300 | 5400 | 5200 | 5300 | 5200 | 5300 |
| 5% weight loss temperature (° C.) | | 377 | 338 | 336 | 337 | 337 | 333 | 330 |
| Alkali | Immersion for 30 | Good | Good | Good | Slight | Slight | Good | Slight |
| solubility | seconds | | | | residue | residue | | residue |
| | | | | | observed | observed | | observed |
| | Immersion for 60 | Good | Good | Good | Good | Good | Good | Good |
| | seconds | | | | | | | |

| | | | | | | | |
|---|---|---|---|---|---|---|---|
| Photocurability | Good | Good | Good | Good | Good | Good | Good |
| Adhesion after PCT treatment | ◯◯ | ◯◯ | ◯◯ | ◯◯ | ◯◯ | ◯ | ◯ |

| | | | Compar- | Compar- | Compar- | Compar- |
|---|---|---|---|---|---|---|
| | | Exam- | ative | ative | ative | ative |
| | | ple | Exam- | Exam- | Exam- | Exam- |
| | | 8 | ple 1 | ple 2 | ple 3 | ple 4 |
| Polymer solution | | A-8 | B-1 | B-2 | B-3 | B-4 |
| Polymerization | N-benzylmaleimide | 45 | 25 | 30 | 30 | 45 |
| step | N-phenylmaleimide | — | — | — | — | — |
| | Acrylic acid | 20 | 18.8 | 18.8 | 24 | 18.8 |
| | Vinyl toluene | 35 | 56.2 | 51.2 | 46 | 31.2 |
| | Styrene | — | — | — | — | — |
| | 2-Hydroxyethyl | — | — | — | — | 5 |
| | methacrylate | | | | | |
| | 3-Mercaptopropionic | 2.2 | 5 | 5 | 5 | 5 |
| | acid | | | | | |
| | 3-Mercapto-1,2- | 1.1 | — | — | — | — |
| | propanediol | | | | | |
| Additional | Glycidyl | 9.5 | — | 9.5 | 17.4 | 9.5 |
| step | methacrylate | | | | | |
| Acid value (mgKOH/g) | | 118 | 165 | 122 | 122 | 121 |
| Double bond equivalent (g/eq) | | 1690 | None | 1710 | 1000 | 1710 |
| Ester bond equivalent (g/eq) | | 840 | None | 860 | 500 | 670 |
| Imide equivalent (g/eq) | | 470 | 790 | 710 | 760 | 480 |
| Weight average molecular weight (Mw) | | 8100 | 4800 | 5100 | 5400 | 5300 |
| 5% weight loss temperature (° C.) | | 343 | 374 | 336 | 320 | 329 |
| Alkali | Immersion for 30 | Good | Residue | Residue | Residue | Good |
| solubility | seconds | | observed | observed | observed | |
| | Immersion for 60 | Good | Slight | Slight | Slight | Good |
| | seconds | | residue | residue | residue | |
| | | | observed | observed | observed | |

| | | | | | |
|---|---|---|---|---|---|
| Photocurability | Good | Good | Good | Good | Good |
| Adhesion after PCT treatment | ◯◯ | Δ | Δ | X | Δ |

TABLE 2

| | Exam- | Exam- | Exam- | Exam- | Exam- | Exam- | Exam- |
|---|---|---|---|---|---|---|---|
| | ple | ple | ple | ple | ple | ple | ple |
| (parts) | 9 | 10 | 11 | 12 | 13 | 14 | 15 |
| A-1 | 100 | — | — | — | — | — | — |
| A-2 | — | 100 | — | — | — | — | — |
| A-3 | — | — | 100 | — | — | — | — |
| A-4 | — | — | — | 100 | — | — | — |
| A-5 | — | — | — | — | 100 | — | — |
| A-6 | — | — | — | — | — | 100 | — |
| A-7 | — | — | — | — | — | — | 100 |
| A-8 | — | — | — | — | — | — | — |
| B-1 | — | — | — | — | — | — | — |
| B-2 | — | — | — | — | — | — | — |
| B-3 | — | — | — | — | — | — | — |
| B-4 | — | — | — | — | — | — | — |
| 828EL | 55 | 40 | 34 | 40 | 40 | 40 | 40 |
| Triphenylphosphine | 0.5 | — | — | — | — | — | — |
| PGMEA | Amount that gives resin solids of 30% | | | | | | |
| Tg (° C.) | 114 | 106 | 110 | 107 | 105 | 103 | 101 |
| α₅₀₋₁₅₀ (ppm/° C.) | 125 | 129 | 122 | 127 | 130 | 132 | 134 |

| | | Compar- | Compar- | Compar- | Compar- |
|---|---|---|---|---|---|
| | Exam- | ative | ative | ative | ative |
| | ple | Exam- | Exam- | Exam- | Exam- |
| (parts) | 16 | ple 5 | ple 6 | ple 7 | ple 8 |
| A-1 | — | — | — | — | — |
| A-2 | — | — | — | — | — |
| A-3 | — | — | — | — | — |
| A-4 | — | — | — | — | — |
| A-5 | — | — | — | — | — |
| A-6 | — | — | — | — | — |
| A-7 | — | — | — | — | — |
| A-8 | 100 | — | — | — | — |
| B-1 | — | 100 | — | — | — |
| B-2 | — | — | 100 | — | — |
| B-3 | — | — | — | 100 | — |
| B-4 | — | — | — | — | 100 |
| 828EL | 39 | 55 | 40 | 40 | 40 |
| Triphenylphosphine | — | 0.5 | — | — | — |

| | |
|---|---|
| PGMEA | Amount that gives resin solids of 30% |

| | | | | | |
|---|---|---|---|---|---|
| Tg (° C.) | 109 | 95 | 92 | 95 | 99 |
| α₅₀₋₁₅₀ (ppm/° C.) | 119 | 156 | 154 | 139 | 136 |

Tables 1 and 2 demonstrated that the polymers of the examples which contained a structural unit derived from a maleimide-based monomer, a structural unit derived from an aromatic monomer, and a structural unit derived from an acid group-containing monomer, which had an imide equivalent weight of 670 g/eq or less, and in which the amount of a structural unit derived from a primary hydroxy group-containing monomer was less than 5% by mass were excellent in all of photocurability, alkali solubility, heat resistance, moisture resistance, and thermomechanical properties.

Among the polymers of the examples, the polymers (A-1) to (A-3), which were prepared using N-benzylmaleimide and vinyltoluene without using 2-hydroxyethyl methacrylate and which had a low imide equivalent weight, exhibited better results.

Furthermore, the polymer (A-8), which was prepared using 3-mercapto-1,2-propanediol (a hydroxy group-containing mercaptan) as a chain transfer agent, exhibited further improved heat resistance and thermomechanical properties while maintaining good alkaline developability.

On the other hand, the comparative polymers (B-1) to (B-4), which did not satisfy at least one of the above features, were inferior in moisture resistance and thermomechanical properties. The polymers (B-1) to (B-3) with a high imide equivalent weight provided cured films having a high coefficient of linear expansion, and a difference in coefficient of linear expansion between each cured film and the substrate was large. This resulted in the interface serving as a weak point, which lowered the adhesion therebetween. The polymer (B-4) containing 5% by mass or more of 2-hydroxyethyl methacrylate had high hydrophilicity, low heat resistance, and low moisture resistance. Thus, the adhesion presumably deteriorated.

The polymer of the present disclosure and a resin composition containing the polymer were also excellent in photocurability and alkali solubility, and therefore could be suitably used as a resist polymer and a photosensitive resin composition, respectively. The polymer of the present disclosure and a resin composition containing the polymer were also excellent in heat resistance, moisture resistance, and thermomechanical properties (low coefficient of linear expansion), and therefore could be suitably used as an interlayer insulating film material and the like.

1. A resist polymer comprising:
a structural unit (A) derived from a maleimide-based monomer;
a structural unit (B) derived from an aromatic monomer; and
a structural unit (C) derived from an acid group-containing monomer,
an amount of a structural unit (D) derived from a primary hydroxy group-containing monomer being less than 5% by mass based on 100% by mass of all structural units of the polymer,
the polymer having an imide equivalent weight of 670 g/eq or less.

2. The resist polymer according to claim 1,
wherein the polymer has an ester bond equivalent weight of 500 g/eq or more.

3. The resist polymer according to claim 1, further comprising a structural unit (E) containing a polymerizable double bond in a side chain.

4. The resist polymer according to claim 3,
wherein the structural unit (E) includes a structural unit represented by the following formula (1): 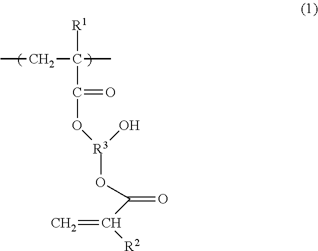
wherein R¹ and R² are the same as or different from each other and each represent a hydrogen atom or a C1-C6 hydrocarbon group; and R³ represents a C1-C10 trivalent hydrocarbon group.

5. The resist polymer according to claim 1,
wherein the structural unit (B) derived from an aromatic monomer includes a structural unit represented by the following formula (2): 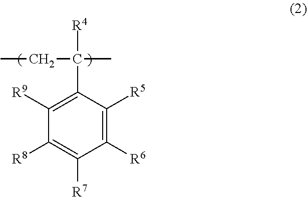
wherein R⁴ to R⁹ are the same as or different from each other and each represent a hydrogen atom or a C1-C6 hydrocarbon group.

6. The resist polymer according to claim 1,
wherein the polymer has a weight average molecular weight of 20,000 or less.

7. A photosensitive resin composition comprising:
the resist polymer according to claim 1; and
an organic solvent.

8. The photosensitive resin composition according to claim 7, further comprising a thermal crosslinking agent.

9. An interlayer insulating film comprising a cured product of the photosensitive resin composition according to claim 7.

10. A method for producing a polymer, comprising
polymerizing a monomer component in the presence of a solvent,
the monomer component comprising a maleimide-based monomer (a) in an amount of 35 to 60% by mass, an aromatic monomer (b) in an amount of 10 to 60% by mass, and an acid group-containing monomer (c) in an amount of 5 to 30% by mass, in 100% by mass of the monomer component,
an amount of a primary hydroxy group-containing monomer (d) in 100% by mass of the monomer component being less than 5% by mass,
the solvent including an ester solvent.
